(19) United States
(12) Patent Application Publication
(10) Pub. No.: US 2006/0027451 A1
(43) Pub. Date: Feb. 9, 2006

(54) Methods for sputtering a target material by intermittently applying a voltage thereto and related apparatus, and methods of fabricating a phase-changeable memory device employing the same

(76) Inventors: Jeong-Hee Park, Gyeonggi-do (KR); Jang-Eun Lee, Gyeonggi-do (KR); Sung-Lae Cho, Gyeonggi-do (KR)

Correspondence Address: MYERS BIGEL SIBLEY & SAJOVEC, PO BOX 37428, RALEIGH, NC, 27627, US

(21) Appl. No.: 11/198,725

(22) Filed: Aug. 5, 2005

(30) Foreign Application Priority Data
Aug. 6, 2004 (KR) 2004-0062165

(51) Int. Cl. C23C 14/34; C23C 14/32

(52) U.S. Cl. 204/192.26; 204/192.12; 204/192.25; 204/298.08

(57) ABSTRACT

A method of sputtering to deposit a target material onto a substrate includes supplying an ionized gas to the substrate and the target material. A first DC bias voltage having a polarity opposite that of the ionized gas is applied to the target material to attract ions theretoward. A second DC bias voltage having a polarity opposite that of the first DC bias voltage is intermittently applied to the target material to reduce ion accumulation thereon. Related apparatus and methods of fabricating phase-changeable memory devices are also discussed.

### CROSS-REFERENCE TO RELATED APPLICATIONS

This application claims priority under 35 U.S.C. § 119 from Korean Patent Application No. 10-2004-0062165 filed on Aug. 6, 2004, the disclosure of which is hereby incorporated by reference herein in its entirety.

### BACKGROUND OF THE INVENTION

The present invention relates to semiconductor device fabrication methods, and more particularly, to sputtering methods and related devices.

DC sputtering technology has been widely used in methods for forming a thin film on a substrate. More particularly, DC sputtering technology has been applied in a variety of industrial fields, for example, in semiconductor manufacturing processes. In DC sputtering, a vacuum atmosphere may be provided in a chamber including a target material disposed over a substrate. A negative DC voltage may be applied between the target and the substrate. Argon gas may then be introduced into the chamber and ionized. As such, the argon gas ions may be accelerated toward the target and may collide with the target, so that atoms may be sputtered from the target and deposited as a thin film on a surface of the substrate.

In the process described above, the thin film may be an insulation layer or a conductive layer. Exemplary conductive layers may include an aluminum layer, a copper layer, a titanium layer, a metal nitride layer, a conductive metal oxide layer, etc. Exemplary insulation layers may include an oxide layer, a nitride layer, a thin-film containing impurity such as a chalcogen compound, etc. In some instances, the thin film containing the chalcogen compound may be disposed between electrodes.

A potential problem associated with sputtering is arcing. Arcing can occur when a conductive layer and/or an insulation layer are formed by DC sputtering. For example, in forming a conductive layer by DC sputtering, a surface of the target may become polluted, such that an insulating layer may be formed on portions of the surface of the target. As such, when a negative voltage is applied to the polluted target, argon ions may accumulate on portions of the surface of the target. Alternatively, in forming an insulation layer by DC sputtering, argon ions may accumulate on the surface of the substrate when a negative voltage is applied to the target. The accumulated argon ions at the surface of the target may cause arcing, such that a portion of the target may melt and become attached to the surface of the substrate. Especially in materials that melt at lower temperatures than metal (for example, chalcogen), the arcing may present serious problems.

Problems relating to the formation of a chalcogen compound layer by DC sputtering will now be described with reference to FIGS. 1A and 1B. FIGS. 1A and 1B illustrate a conventional DC sputtering apparatus for forming a chalcogen compound layer on a substrate. Referring to FIG. 1A, a sputtering apparatus may include substrate 13 on which a sputtered material may be deposited, a susceptor 11 on which the substrate 13 is placed, a target 15 (formed of a chalcogen compound) positioned opposite to the substrate 12, and a DC power supply 17 configured to apply a negative voltage to the target 15. The susceptor 11 and the substrate 13 may be grounded to provide a voltage differential between the substrate 13 and the target 15. Argon gas may be introduced to the substrate 13 and the target 15, such that argon plasma may be generated by the voltage difference between the substrate 13 and the target 15. Accordingly, argon ions (Ar+) 19 may collide with a surface of the target 15, and chalcogen atoms may be sputtered from the target 15 and may be deposited on the substrate 13.

However, the chalcogen compound may have relatively high resistivity, and as such, may exhibit relatively high insulating characteristics. Therefore, argon ions 19a may accumulate on the surface of the target 15 when the negative voltage is applied thereto. If the argon ions 19a continue to accumulate, arcing may occur due to an electric field between the accumulated argon ions 19a and the target 15. Accordingly, portions of the chalcogen target 15 (which may have a relatively low melting temperature) may be melted by the arcing, such that melted particles 23 of the target 15 may fall toward the substrate 13 and may become attached on the substrate 13, as shown in FIG. 1B. Properties of the melted particles 23 may differ from properties of the sputtered atoms (M) 21 that are deposited on substrate 13. As a result, it may be difficult to form a chalcogen compound layer (or other phase-changeable material layer) having excellent properties using conventional DC sputtering methods.

### SUMMARY OF THE INVENTION

According to some embodiments of the present invention, a method of sputtering to deposit a target material onto a substrate includes supplying an ionized gas to the substrate and the target material. A first DC bias voltage having a polarity opposite that of the ionized gas is applied to the target material to attract ions theretoward. A second DC bias voltage having a polarity opposite that of the first DC bias voltage is intermittently applied to the target material to reduce ion accumulation thereon. Accordingly, the target material may be deposited onto the substrate responsive to applying the first DC bias voltage and intermittently applying the second DC bias voltage to the target material.

In some embodiments, the second DC bias may be intermittently applied for a duration that is shorter than a duration of applying the first DC bias voltage over a predetermined time period. Also, the second DC bias voltage may be periodically applied to the target material. As such, a DC pulse that periodically switches between the first DC bias voltage and the second DC bias voltage may be applied to the target material.

In other embodiments, the DC pulse may be a squarewave that is applied to the target material. A period of the squarewave may include a first portion having an amplitude at the first DC bias voltage for a first duration and a second portion having an amplitude at the second DC bias voltage for a second duration. The second duration may be less than the first duration. For example, the period of the squarewave may be about 1 μs to about 1 ms, and the second duration may be about 1 μs to about 100 μs. In some embodiments, the frequency of the squarewave may be about 1 kHz to about 10 MHz. Also, the amplitude of the second portion of the period of the squarewave may be about 5% to about 95% of the sum of the amplitudes of the first and second portions.

In some embodiments, the first DC bias voltage may be a negative voltage, and the second DC bias voltage may be a positive voltage.

In other embodiments, the method may include applying a magnetic field to the target material to attract ions theretoward.

In some embodiments, supplying an ionized gas may include supplying an inert gas and a reaction gas to the substrate and the target material, and ionizing the inert gas and the reaction gas. The inert gas may be provided at a flow rate that is greater than a flow rate of the reaction gas. For example, the inert gas may be argon (Ar), and the reaction gas may be nitrogen (N).

In other embodiments, the target material may be chalcogen. As such, a nitrogen-doped chalcogen layer having a resistivity greater than that of chalcogen may be formed on the substrate responsive to applying the first DC bias voltage and intermittently applying the second DC bias voltage to the target material.

In some embodiments, the substrate may include a first electrode thereon, and the target material may be a phase-changeable material. As such, atoms of the target material may be deposited onto the first electrode to form a phase-changeable layer thereon responsive to applying the first DC bias voltage and intermittently applying the second DC bias voltage. A second electrode may be formed on the phase-changeable layer to define a phase changeable memory cell.

According to further embodiments of the present invention, a method of fabricating a phase-changeable memory device includes forming a first electrode on a substrate adjacent a target comprising a phase-changeable material. An ionized gas is supplied to the substrate and the target, and a first DC bias voltage having a polarity opposite that of the ionized gas is applied to the target to attract ions theretoward. A second DC bias voltage having a polarity opposite that of the first DC bias voltage is intermittently applied to the target to reduce ion accumulation thereon. A phase-changeable material layer is deposited on the first electrode responsive to applying the first DC bias voltage and intermittently applying the second DC bias voltage. A second electrode is formed on the phase-changeable material layer to define a phase changeable memory cell.

In some embodiments, a DC pulse that periodically switches between the first DC bias voltage and the second DC bias voltage is applied to the target. For example, the DC pulse may be a squarewave. A period of the squarewave may include a first portion having an amplitude at the first voltage for a first duration and a second portion having an amplitude at the second voltage for a second duration, and wherein the second duration is less than the first duration.

In other embodiments, the target may include chalcogen. An argon (Ar) gas and a nitrogen (N) gas may be supplied to the substrate and the target material, and the argon (Ar) gas and the nitrogen (N) gas may be ionized. A nitrogen-doped chalcogen layer having a resistivity greater than that of chalcogen may be formed on the substrate responsive to applying the first DC bias voltage and intermittently applying the second DC bias voltage to the target.

In some embodiments, an upper conductive layer may be connected to the second electrode by a conductive plug. In other embodiments, the upper conductive layer may be directly on the second electrode.

According to still further embodiments of the present invention, a sputtering apparatus includes a susceptor including a substrate thereon, a target material opposite the substrate, a gas supply configured to provide an ionized gas to the substrate and the target material, and a voltage source. The voltage source may be configured to apply a first DC bias voltage having a polarity opposite that of the ionized gas to the target material to attract ions theretoward. The voltage source may also be configured to intermittently apply a second DC bias voltage having a polarity opposite that of the first DC bias voltage to the target material to reduce ion accumulation thereon. The target material may thereby be deposited onto the substrate responsive to applying the first DC bias voltage and intermittently applying the second DC bias voltage to the target material.

In some embodiments, the voltage source may be configured to apply the first DC bias voltage for a first duration and intermittently apply the second DC bias voltage for a second duration. The first duration may be greater than the second duration over a predetermined time period.

In other embodiments, the voltage source may be configured to periodically apply the second DC bias voltage to the target material. For example, the voltage source may be a DC pulse generator configured to apply a DC pulse to the target material that periodically switches between the first DC bias voltage and the second DC bias voltage.

In some embodiments, the DC pulse generator may include a DC bias source configured to provide a DC voltage, and a DC pulse converter configured to convert the DC voltage into a squarewave. A period of the squarewave may include a first portion having an amplitude at the first DC bias voltage for a first duration and a second portion having an amplitude at the second DC bias voltage for a second duration. The second duration may be less than the first duration. The first DC bias voltage may be a negative voltage, and the second DC bias voltage may be a positive voltage.

In other embodiments, the apparatus may further include a magnet adjacent the target material. The magnet may be configured to apply a magnetic field to the target material to attract ions theretoward.

In some embodiments, the gas supply may be configured to supply an inert gas and a reaction gas to the substrate and the target material. For example, the inert gas may be argon (Ar), and the reaction gas may be nitrogen (N).

In other embodiments, the target material may include chalcogen. The apparatus may thereby be configured to deposit chalcogen atoms from the target material onto the substrate to form a nitrogen-doped chalcogen layer thereon. For example, the nitrogen-doped chalcogen layer may include about 0.25% to about 25% nitrogen atoms. The nitrogen-doped chalcogen layer may have a resistivity greater than that of chalcogen.

In some embodiments, a DC pulse swinging between a positive voltage and a negative voltage may be applied to the target material. As a result, a positive bias voltage may be applied to the target at intermittent intervals of time, which may prevent argon ions (Ar+) from accumulating on a surface of the target. A chalcogen compound layer may thereby be formed on the substrate, as arcing may not be generated during the sputtering process.

In other embodiments, periodically applying the positive DC bias may not only decrease a deposition rate of the chalcogen compound layer, but may also increase the reaction time for the nitrogen atoms and the chalcogen compound of the target. A chalcogen compound layer doped with nitrogen atoms having a smaller crystal size may thereby be formed on the substrate, as the sputtered atoms of the target and the nitrogen radical may be sufficiently reacted. A chalcogen compound layer with a smaller crystal size may require a decreased reset/set current in order to convert the chalcogen compound into a solid and/or amorphous state as compared with thin films having a relatively large crystal size. Moreover, a chalcogen compound doped with nitrogen atoms and silicon atoms may have a relatively small crystal size as compared with chalcogen compounds not doped with nitrogen atoms and/or silicon atoms.

### BRIEF DESCRIPTION OF THE DRAWINGS

FIGS. 1A and 1B illustrate a conventional DC sputtering apparatus for forming a thin film on a substrate;

FIG. 2 is a graph illustrating nitrogen concentration and resistivity of GST (Ge—Sb—Te) doped with nitrogen atoms in accordance with some embodiments of the present invention;

FIG. 3 is a graph illustrating annealing temperature and resistivity of GST doped with nitrogen atoms as compared to undoped GST in accordance with some embodiments of the present invention;

FIG. 4 is a cross-sectional view illustrating a phase-changeable memory cell in accordance with some embodiments of the present invention;

FIG. 5 is a cross-sectional view illustrating a phase-changeable memory cell in accordance with further embodiments of the present invention;

FIG. 6 illustrates a sputtering apparatus in accordance with some embodiments of the present invention;

FIG. 7 illustrates a voltage wave applied to a target material according to some embodiments of the present invention;

FIGS. 8A and 8B illustrate sputtering methods in accordance with some embodiments of the present invention;

FIG. 9 is a graph illustrating variations in resistivity before and after thermal processing for about five minutes at about 350° C. in an argon atmosphere for a chalcogen compound doped with nitrogen atoms formed using a pulsed DC bias in accordance with some embodiments of the present invention as compared with conventional methods;

FIG. 10 is a graph illustrating X-ray diffraction for a chalcogen compound doped with nitrogen atoms formed according to some embodiments of the present invention as compared with conventional methods after thermal processing;

FIGS. 11 through 17 are cross-sectional views illustrating methods of fabricating a phase-changeable memory device including a chalcogen compound layer formed by sputtering methods in accordance with some embodiments of the present invention; and

FIGS. 18 and 19 are cross-sectional views illustrating methods of fabricating a phase-changeable memory device including a chalcogen compound layer formed by sputtering in accordance with further embodiments of the present invention.

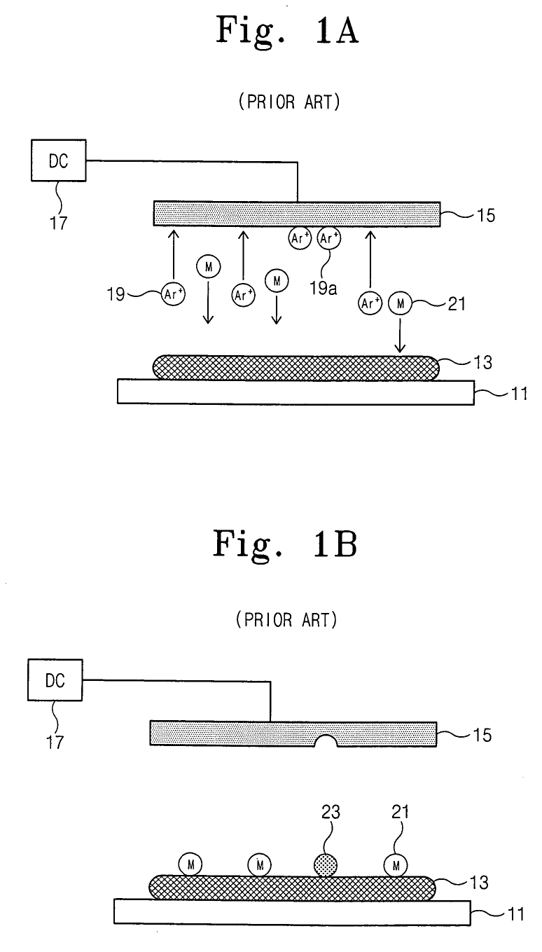

### DETAILED DESCRIPTION OF EMBODIMENTS OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an ” and “the” are intended to include the plural forms as well, unless the context clearly indicates otherwise. It will also be understood that the term “and/or” as used herein refers to and encompasses any and all possible combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

The present invention may relate to an apparatus and methods for sputtering. The apparatus and method of the present invention can be suitably adapted for fabrication of phase-changeable memory devices. The chalcogen compounds described herein may include Ge—Sb—Te, As—Sb—Te, As—Ge—Sb—Te, Sn—Sb—Te, In—Sn—Sb—Te, Ag—In—Sb—Te, a group-5A element-Sb—Te, a group-6A element-Sb—Te, a group-5A element-Sb—Se, a group-6A element-Sb—Se as known. In some embodiments, the chalcogen compound may be Ge—Sb—Te (hereinafter, referred to as ‘GST’). A physical state of the chalcogen compound may depend on heat transferred thereto, which may be controlled by a current applied thereto. As such, the physical state of a GST layer may depend on the duration and magnitude of a current applied thereto. The GST (or other chalcogen compound) layer may be used to form a memory cell, as its resistivity may be changed based on its physical state. For example, resistivity may be relatively low in a crystalline state, while resistivity may be relatively high in an amorphous state, thereby providing two distinct logical ‘states’ for use in data storage.

More particularly, when a relatively high current is applied to the GST for a short time so as to heat the GST to a temperature near its melting point (for example, about 610° C.) and the GST is rapidly cooled, the heated portion of the GST may be converted into the amorphous state (i.e., a reset state). Alternatively, when a relatively low current is applied to the GST for a longer time so as to heat the GST to a temperature below its melting point (for example, about 450° C.) and the GST is rapidly cooled, the heated portion of the GST may be converted to the crystalline state (i.e., a set state).

Accordingly, formation of the chalcogen compound layer may be of great importance to operation of the phase-changeable memory device. As mentioned above, conventional methods of forming the chalcogen compound layer using a sputtering process may result in arcing due to the accumulated argon ions at the surface of the chalcogen-containing target.

Furthermore, it may be desirable to decrease the crystal size of the chalcogen compound (and thereby increase the resistivity thereof) so as to decrease current required to convert the chalcogen compound between the set and reset states, for example, for higher device integration. Embodiments of the present invention illustrate that the resistivity of the chalcogen compound may increase when the chalcogen compound is doped with nitrogen atoms, silicon atoms, or a combination thereof.

However, when a chalcogen compound doped with nitrogen atoms, silicon atoms, or a combination thereof is formed by conventional sputtering methods, arcing may occur. For example, nitrogen ions may accumulate on the surface of the chalcogen compound target, such that an insulation property of the target may be decreased, and the argon ions may be continuously accumulated thereon. Therefore, sputtering methods according to the present invention can be advantageously used to form chalcogen compounds doped with nitrogen.

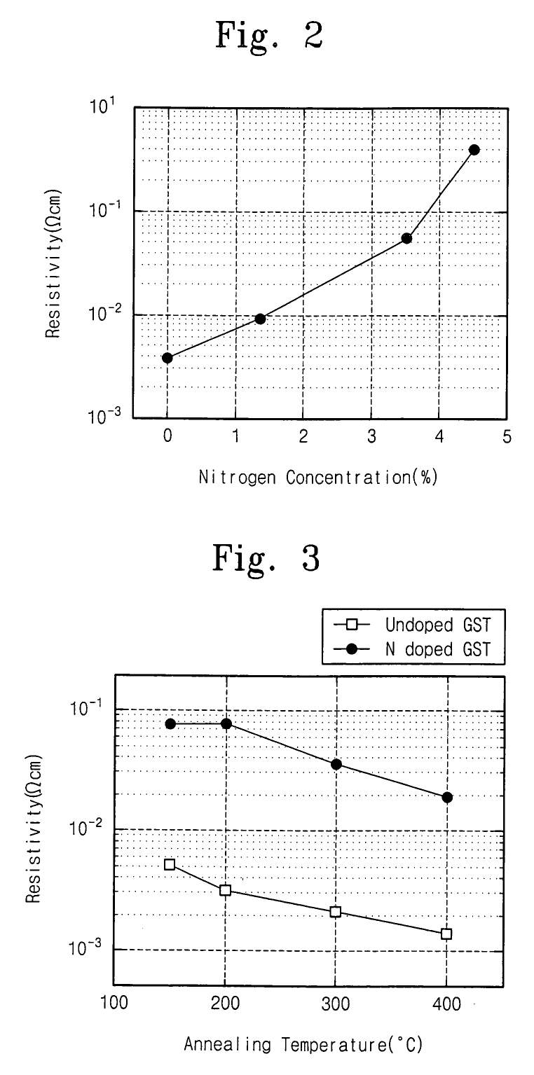

FIG. 2 is a graph illustrating a relationship between nitrogen concentration and resistivity of nitrogen-doped GST (Ge—Sb—Te—N) in accordance with some embodiments of the present invention. In a FIG. 2, the horizontal axis (X-axis) represents a concentration (%) of nitrogen atoms (i.e. atomic percent) contained in the GST, and the vertical axis (Y-axis) represents the resistivity (specific resistance) (Ωcm). As shown in FIG. 2, as the concentration of the nitrogen atoms is increased, the resistivity is also increased.

FIG. 3 is a graph illustrating a relationship between annealing temperature and resistivity of nitrogen-doped GST in accordance with some embodiments of the present invention as compared to conventional Ge—Sb—Te. In a FIG. 3, the horizontal axis represents the annealing temperature and the vertical axis represents the resistivity (Ωcm). Also, symbol -∘- represents the resistivity of GST doped with 7% of nitrogen atoms in accordance with some embodiments of the present invention and symbol -□- represents the resistivity of the conventional Ge—Sb—Te. Referring to FIG. 3, after annealing is carried out at a temperature of about 400° C., conventional Ge—Sb—Te has a resistivity of about 2 mΩcm. However, the GST doped with nitrogen atoms has a resistivity of about 20 mΩcm. Therefore, the resistivity of GST formed according to some embodiments of the present invention may be about ten times greater than conventionally formed GST.

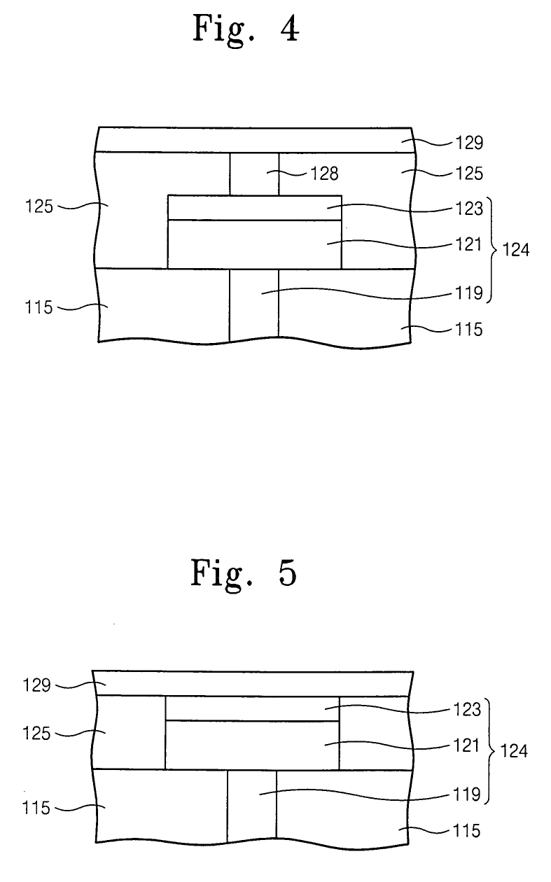

FIG. 4 is a cross-sectional view illustrating a phase-changeable memory cell in accordance with some embodiments of the present invention. In a FIG. 4, reference number 119 represents a first electrode, reference number 121 represents a chalcogen compound layer (or other phase-changeable material layer), and reference number 123 represents a second electrode. Reference number 115 represents a lower insulation layer in which the first electrode 119 is formed, and reference number 125 represents an upper insulation layer in which the second electrode 123 is formed. Also, reference number 129 represents an upper conductive layer/metal wiring, and reference number 128 represents a conductive plug that is disposed between the upper conductive layer 129 and the second electrode 123 so as to electrically connect the upper conductive layer 129 and the second electrode 123. As shown in FIG. 4, the first electrode 119 may be a contact plug that is formed in a contact hole of the lower insulation layer 115. The chalcogen compound layer 121 is successively formed on the lower insulation layer 115 and the first electrode 119, and is electrically connected to the first electrode 119. The second electrode 123 is formed on the chalcogen compound layer 121. The conductive plug 128, which is formed in the contact hole of the upper insulation layer 125, is electrically connected to the second electrode 123 and the upper conductive layer 129.

Accordingly, the contact area between the first electrode 119 and the chalcogen compound layer 121 may depend on a diameter of the first electrode 119. As such, the physical structure (i.e., amorphous or crystalline) of the chalcogen compound layer 121 may depend on the contact area. The second electrode 123 is formed on an entire surface of the chalcogen compound layer 121, such that contact area therebetween is increased and/or maximized. When an electric current flows between the first and second electrodes 119 and 123 through the chalcogen compound layer 121, a change in physical state (i.e., amorphous to crystalline or vice versa) occurs at the contact area. In some embodiments, both the first electrode 119 and second electrode 123 may be formed as contact plugs as shown in FIG. 4. The first electrode 119, the chalcogen compound layer 121, and the second electrode 123 form a variable resistor 124, that is, a phase-changeable memory cell 124.

The first electrode 119 and the second electrode 123 may be a conductive material containing nitrogen, carbon, titanium, tungsten, molybdenum, tantalum, titanium silicide, tantalum silicide, etc., either alone or in combination. For example, a conductive material containing nitrogen atoms may be one of a titanium nitride (TiN), tantalum nitride (TaN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON) and tantalum oxynitride (TaON). Also, a conductive material containing carbon atoms may be, for example, a conductive carbon such as graphite.

The conductive plug 128 that is electrically connected to the second electrode 123 and the upper conductive layer 129 may be formed of aluminum (Al), aluminum-copper (Al—Cu) alloy, aluminum-copper-silicon (Al—Cu—Si) alloy, tungsten silicide (TiSi), copper (Cu), tungsten titanium (TiW), tantalum (Ta), molybdenum (Mo), and/or tungsten (W). The upper conductive layer 129 may function as a bit line for accessing data stored in the phase-changeable memory cell 124. The upper conductive layer 129 also may be formed of aluminum (Al), aluminum-copper (Al—Cu) alloy, aluminum-copper-silicon (Al—Cu—Si) alloy, tungsten silicide (TiSi), copper (Cu), tungsten titanium (TiW), tantalum (Ta), molybdenum (Mo), and/or tungsten (W).

In FIG. 4, the second electrode 123 functions as a barrier layer that prevents a reaction between the conductive plug 128 and the chalcogen film 121.

FIG. 5 is a cross-sectional view illustrating a phase-changeable memory cell in accordance with another embodiment of the present invention. The phase-changeable memory cell shown in FIG. 5 is similar to that of FIG. 4, except for a direct electrical connection between the second electrode 123 and the upper conductive layer 129. In other words, in. FIG. 5, the upper conductive layer 129 is directly connected to the second electrode 123 without the conductive plug therebetween.

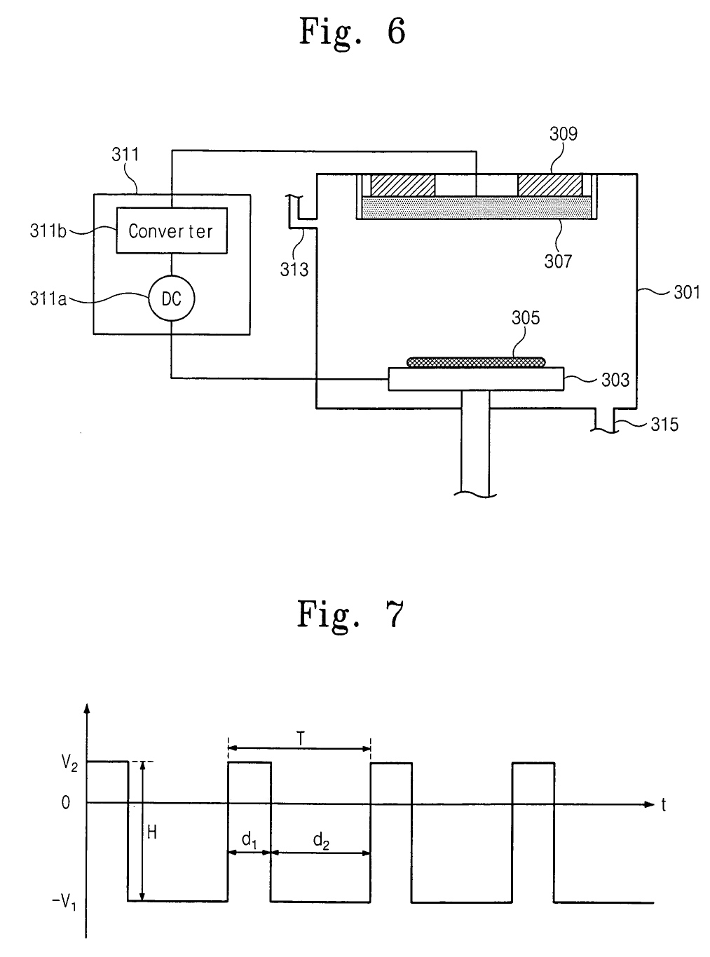

An exemplary sputtering apparatus according to some embodiments of the present invention that is configured to deposit a chalcogen or other phase-changeable material compound will now be described with reference to FIG. 6.

Referring now to FIG. 6, a sputtering apparatus 300 includes a reaction chamber 301 that accommodates a substrate 305 and a chalcogen compound target 307. A DC pulse generator 311 is connected between the substrate 305 and the target 307 so as to apply a DC pulse that swings between a positive voltage and a negative voltage. The substrate is placed on a susceptor 303. A magnet 309 may be mounted on a side of the target 307 that is opposite the substrate 305. As a result, when sputtering is performed using the sputtering apparatus 300, the deposition rate of the thin film that is formed on the substrate 305 may be increased, for example, by using the magnet 309 to generate a higher plasma density generated around the target 307. Accordingly, more atoms may be sputtered from the target as compared with conventional methods.

Still referring to FIG. 6, a gas supply line 313 is connected to the reaction chamber 301 so as to supply an inert gas and a reaction gas, which may be used for doping the chalcogen compound. Also, a gas exhaust line 315 is connected to the reaction chamber 301. The reaction chamber 301 may be maintained at a high vacuum atmosphere by a vacuum pump (not shown).

More particularly, argon gas may be introduced into the reaction chamber 301 through the gas supply line 313, for example, at a flow rate of about 15 sccm to about 150 sccm. Also, nitrogen gas may be introduced into the reaction chamber 301, for example, at a flow rate of about 10 sccm or less. A pressure of the reaction chamber 301 may be about 0.1 to about 1 mTorr, and a temperature of the reaction chamber 301 may be about 100 to about 350° C.

The DC pulse generator 311 applies a DC pulse that switches between a positive voltage and a negative voltage to the target 307 and the substrate 305, as shown in FIG. 7. The DC pulse may be generated by a DC bias supplier 31 la and a DC pulse converter 311b, which converts a DC voltage provided by the DC bias supplier 311a into a square-wave type pulse voltage. Generation of a DC pulse is well-known in the art. The DC bias generated by the DC bias supply 311a may have a range from about 100 Watts to about 500 Watts.

Still referring to FIG. 7, a frequency of the DC pulse may be about 1 kHz to about 10 MHz. That is, a period (T) of the DC pulse may be about 10E-7 to 10E-3 seconds. A duration (d1) of the positive DC bias V1 may be about 1 μs to about 100 μs. For example, in one period of the DC pulse, the positive DC bias V1 may be applied for a duration d1 of about 1 μs to about 100 μs, and the negative DC bias V2 may be applied for a duration d2 that corresponds to the remainder of the period. The DC pulse has a voltage swing H=V1+V2. Also, the amplitude of the positive voltage may be about 5% to about 95% of the voltage swing (H) of the DC pulse.

An inert gas, for example, argon gas, is introduced into the reaction chamber 301 through the gas supply line 313. The argon gas is ionized by the high voltage pulse that is applied to the target 307 and the substrate 305 using the DC pulse generator 311 to form plasma.

The chalcogen compound target 307 may include Ge—Sb—Te (GST), As—Sb—Te, As—Ge—Sb—Te, Sn—Sb—Te, In—Sb—Te, Ag—In—Sb—Te, a group-5A element-Sb—Te, a group-6A element-Sb—Te, a group-5A element-Sb—Se, a group-6A element-Sb—Se, etc.

In some embodiments, both the argon gas (the inert gas) and the nitrogen gas (the reaction gas) are introduced into reaction chamber 301 via the gas supply line 313 in order to deposit a chalcogen compound layer that is doped with nitrogen atoms onto the substrate 305. As such, the argon gas functions as a carrier gas. Also, where a chalcogen compound layer that is doped with silicon atoms is to be deposited, the target 307 may include Ge—Sb—Te—Si, As—Ge—Sb—Te—Si, Sn—Sb—Te—Si, In—Sn—Sb—Te—Si, Ag—In—Sb—Te—Si, a group-5A element-Sb—Te—Si, a group-6A element-Sb—Te—Si, a group-5A element-Sb—Se—Si, a group-6A element-Sb—Se—Si, etc. If both the inert gas and the nitrogen gas are introduced into reaction chamber 301 via the gas supply line 313, a chalcogen compound layer doped with nitrogen atoms and silicon atoms may be formed.

The concentration of nitrogen atoms in the thin film formed on the substrate may be controlled by adjusting the flow rate of the nitrogen gas that is introduced into the reaction chamber 301. Furthermore, the concentration of silicon atoms in the thin film may be controlled by adjusting the concentration of silicon atoms contained in the target 307.

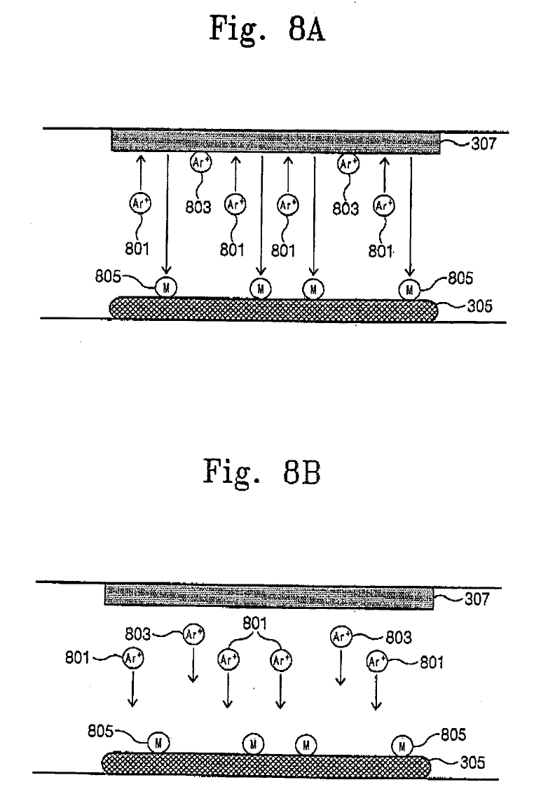

Sputtering methods for depositing a chalcogen compound using a sputtering apparatus according to some embodiments of the present invention (for example, as shown in FIG. 6) will now be described with reference to FIG. 7, FIG. 8A, and FIG. 8B.

Referring again to FIG. 7, a DC pulse that applied to the target 307 and the substrate 305 may be a square-wave. More particularly, the pulsed DC voltage may periodically switch between the positive voltage (V1) and the negative voltage (−V2). The period (T) and the frequency (f) of the pulsed DC voltage can be suitably adjusted, as can the positive bias value and the negative bias value. A duty ratio (indicating a ratio between a duration (d1) of the positive voltage (V1) and a duration (d2) of the negative voltage (−V2) in a given period) may also be adjusted. In some embodiments, DC pulse voltage is generated such that the duration (d2) of the negative voltage (V2) is greater than the duration (d1) of the positive voltage (V1).

During the duration (d2) of the negative voltage (V2) as shown in a FIG. 8A, the high-energy argon ions (Ar+) 803 collide with the target 307 so that atoms (M) 805 contained the target 307 fall toward the substrate 303 and are deposited on the substrate 305. In other words, atoms (M) 805 from the target 307 are sputtered onto the substrate 305 when the negative voltage (V2) is applied to the target 307.

In contrast, during the duration (d1) of the positive voltage (V1), as shown in a FIG. 8B, the positively-charged argon ions (Ar+) 803 (which can accumulate on a portion of the target 307) are repelled from the target 307 by a repulsion force of static electricity. Moreover, the duration (d1) of the positive voltage (V1) provides a sufficient reaction time for the atoms (M) 805 that are sputtered from the target 307 to be deposited on the substrate 305.

A chalcogen compound layer that is doped with nitrogen atoms may be formed on the substrate 305 when nitrogen gas is introduced into the reaction chamber 301 through the gas supply line 313 as a reaction gas. As such, a nitrogen-doped chalcogen compound layer with a smaller crystal structure may be formed. The sputtered atoms (M) 805 and the nitrogen radicals may be sufficiently reacted during the duration (d1) of the positive voltage (V1).

Thus, in some embodiments of the present invention, a DC pulse voltage swinging between a positive voltage and a negative voltage is applied to the target 307 and the substrate 305 so that accumulation of argon ions 803 on the target 307 may be reduced and/or minimized. As such, the argon ions 803 are separated from the target 307 before arcing can be caused by the accumulated argon ions 803. Note that the DC voltage may also switch between the positive and negative voltages intermittently, rather than periodically. Moreover, as used herein, intermittently applying a voltage may include changing the applied voltage from a first voltage level to a second voltage level, for example, from the negative voltage to the positive voltage. Therefore, a chalcogen compound layer having an excellent properties, high resistivity, and smaller crystal structure may be formed.

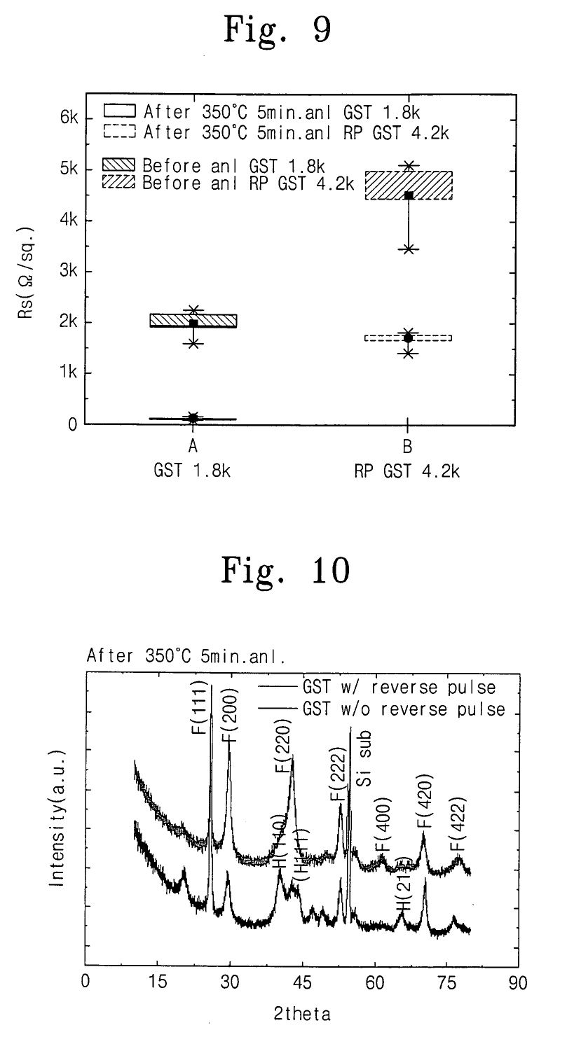

FIG. 9 is graph illustrating variations in resistivity before and after thermal processing (for about five minutes at about 350° C. in an argon atmosphere) of a chalcogen compound doped with nitrogen atoms that is formed using a pulsed DC bias in accordance with some embodiments of the present invention, as compared to a chalcogen compound formed by conventional methods. FIG. 10 is graph illustrating X-ray diffraction for each of the above chalcogen compounds after thermal processing.

As described with reference to FIGS. 9 and 10, a chalcogen compound layer doped with nitrogen having a thickness of about 1,000 Å is formed on a oxide layer. The sputtering is carried out at a temperature of about 200° C. and at a pressure of about 0.5 mTorr, the argon gas is introduced into the reaction chamber at a flow rate of about 41 sccm, and the nitrogen gas is introduced into the reaction chamber at a flow rate of about 2 sccm. Also, a frequency of the pulsed DC bias is about 40 KHz, duration of the positive bias is about 5 μs, and a height of the positive bias is about 15% of a total height of the pulse.

Referring now to FIG. 9, the symbols on the right side of the graph represent a chalcogen compound doped with nitrogen atoms that is formed using a pulsed DC bias voltage in accordance with some embodiments of the present invention, and the symbols on the left side represent a chalcogen compound doped with nitrogen atoms that is formed using conventional methods. As shown in FIG. 9, a resistivity of the chalcogen compound formed according to embodiments of the present invention is about 4.2 KΩ/square cm, which is higher than that of the chalcogen compound formed by conventional methods (i.e., about 1.8 KΩ/square cm). In addition, the chalcogen compound formed using a pulsed DC bias voltage in accordance with some embodiments of the present invention has a resistivity of about 1.7 KΩ/square cm after thermal processing for about 5 minutes at a temperature of about 350° C. Furthermore, a crystal structure of the chalcogen compound after thermal processing has a FCC (faced-centered cubic) structure, as shown in FIG. 10. In contrast, the chalcogen compound formed by conventional methods has a resistivity of about 130 Ω/square cm after thermal processing, and a crystal structure of the chalcogen compound is converted from the FCC structure into a HCP hexagonal closest packing) structure.

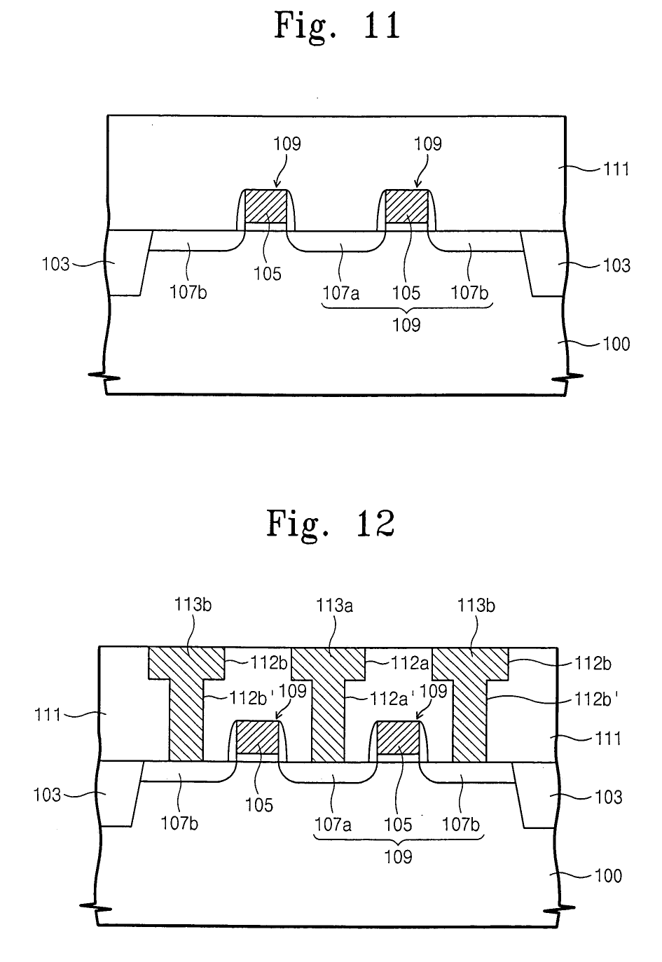

Methods of fabricating a phase-changeable memory device using sputtering methods according to some embodiments of the present invention will now be described with reference to FIGS. 11 through 19.

FIGS. 11 to 17 are cross-sectional views illustrating methods of fabricating a phase-changeable memory device including a chalcogen compound layer formed by sputtering methods in accordance with some embodiments of the present invention.

Referring now to FIG. 11, an isolation region 103 is formed on a surface of a substrate 100 and a transistor 109 is formed on the substrate 100, for example, by a conventional metal-oxide semiconductor field effect transistor (MOSFET) fabrication process. An active region is defined by the isolation region 103, which may be formed by shallow trench isolation (STI) process and/or a local oxidation of silicon (LOCOS) process. The transistor 109 includes a gate electrode 105 that extends on the substrate 100 along a fixed direction, and a source region 107b and a drain region 107a that are formed in the active region of the substrate 101. A channel region between the source region 107b and the drain region 107a conducts current between the source region 107b and the drain region 107a. It will be understood by those skilled in the art that a gate insulation layer is disposed between the gate electrode 105 and the channel region. An insulation interlayer 111 is formed on the substrate 100 covering the transistor 109. The insulation interlayer 111 may be a silicon oxide layer, and may be formed by a chemical vapor deposition (CVD) process.

A process for forming a lower conductive layer/metal wiring 113a will now be described with reference to FIG. 12. The lower conductive layer 113a is electrically connected to the drain region 107a of the transistor 109. For example, the lower conductive layer 113a may extend parallel to the gate electrode 109. In some embodiments, the lower conductive layer 113a may be formed by a dual damascene process. More particularly, the insulation interlayer 111 may be patterned so as to form a contact hole 112a′ (which exposes the drain region 107a) and an interconnection groove 112a. The interconnection groove 112a and the contact hole 112a′ may be filled with a conductive material, so as to form the lower conductive layer 113a electrically connected to the drain region 107a. A contact pad 113b that is electrically connected to the source region 107b may be formed simultaneously with the lower conductive layer 113a. More specifically, a contact hole 112b′ (which exposes the source region 107b) and an opening 112b may be formed simultaneously with the contact hole 112a′ and the interconnection groove 112a, and the contact hole 112b′ and the opening portion 112b may be simultaneously filled with the conductive material when the interconnection groove 112a and the contact hole 112a′ are filled.

The lower conductive layer 113a and the contact pad 113b may be formed by processes other than a dual damascene process. For instance, the insulation interlayer 111 may be patterned to form contact holes exposing the source region 107b and the drain region 107a, and then the conductive material may be formed on the insulation interlayer 111 and patterned so as to fill the contact holes.

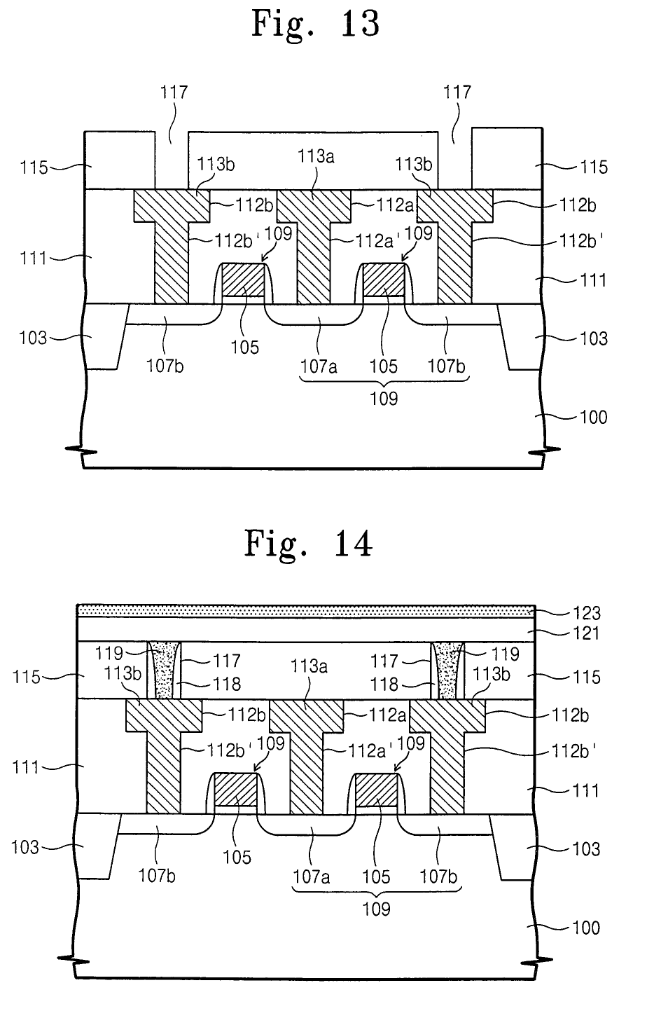

Referring now to FIG. 13, a lower insulation layer 115 is formed on the lower conductive layer 113a, the contact pad 113b and the insulation interlayer 111. The lower insulation layer 115 may be formed, for example, by CVD using a silicon oxide layer. The lower insulation layer 115 is patterned to form a contact hole 117 exposing the contact pad 113b.

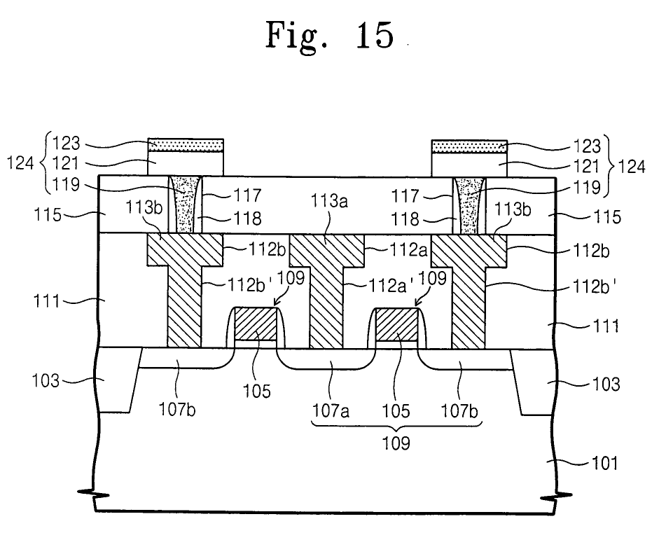

Referring to FIG. 14, an insulation spacer 118 is formed on sidewalls of the contact hole 117 so as to decrease a diameter of the contact hole 117. Thus, a contact area between a first electrode (to be formed in the contact hole 117) and a chalcogen compound layer can be decreased beyond the limits of photolithography. The insulation spacer 118 may be formed by an etch-back process (i.e., without the use of an etching mask) after deposition of an insulation layer in contact hole 117.

Still referring to FIG. 14, after the insulation spacer 118 is formed, a contact hole having a decreased diameter is filled with conductive material to form a first electrode 119 electrically connected to the contact pad 113b. The first electrode 119 may be formed by deposition and planarization of the conductive material, for example, using a chemical-mechanical polishing and/or etch-back process.

The first electrode 119 may be formed of a conductive material containing nitrogen, carbon, titanium, tungsten, molybdenum, tantalum, titanium silicide, tantalum silicide, etc., either alone or in combination. The first electrode 119 may be, formed, for example, by chemical vapor deposition, physical vapor deposition (PVD), and/or atomic layer deposition (ALD). The conductive material containing nitrogen may include titanium nitride (TiN), tantalum nitride (TaN), molybdenum nitride (MoN), niobium nitride (NbN), tungsten silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON), and/or tantalum oxynitride (TaON). Also, a conductive material containing carbon may include a conductive carbon, such as graphite.

Again referring to FIG. 14, after the first electrode 119 is formed, a chalcogen compound layer 121 and a second electrode 123 are sequentially formed on the lower insulation layer 115. The chalcogen compound layer 121 may be formed using the sputtering apparatus and methods as described above, and may be doped with nitrogen atoms. In particular, the atomic concentration of nitrogen atoms contained in the chalcogen compound layer 121 may be about 0.25% through 25% (atomic percent).

The chalcogen compound layer 121 having a thickness of about 100 Å to about 1,000 Å may be formed from the Ge—Sb—Te target at a temperature of about 100° C. to about 350° C. The argon gas may be introduced into the chamber at a pressure of about 10 mmTorr, and the nitrogen gas may be introduced into the chamber at a pressure of about 1 mmTorr. About 500 Watts of DC power may be applied to the target during formation of the chalcogen compound layer 121.

The second electrode 123 may be formed by chemical vapor deposition, physical vapor deposition, and/or atomic layer deposition using the same materials as that of the first electrode 119. As such, the second electrode 123 may be formed of a conductive material containing nitrogen, carbon, titanium, tungsten, molybdenum, tantalum, titanium silicide, tantalum silicide, etc., either alone or in combination.

Referring now to FIG. 15, the second electrode 123 and the chalcogen compound layer 121 are patterned to form a variable resistor 124 (i.e., a phase changeable memory cell having high and low resistance states) that is electrically separated from a neighboring variable resistor.

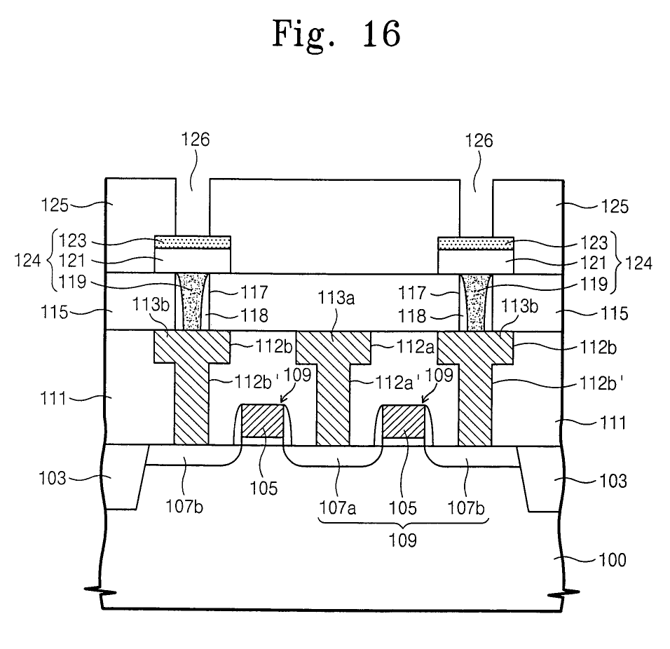

Referring to FIG. 16, an upper insulation layer 125 is formed on the lower insulation layer 115 to cover the variable resistor 124. The upper insulation layer 125 may be a silicon oxide layer that is formed by chemical vapor deposition. The upper insulation layer 125 is patterned to form a contact hole 126 exposing the second electrode 123 of the variable resistor 124.

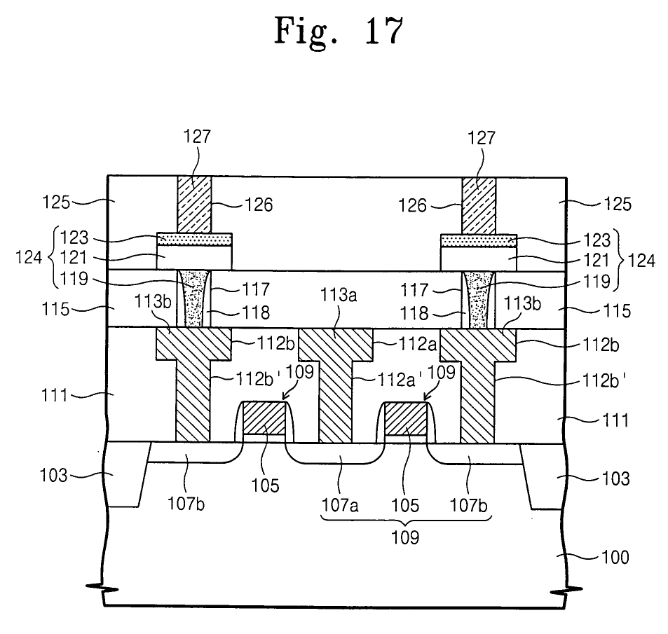

Referring now to FIG. 17, the contact hole 126 is filled with a conductive material to form a conductive plug 127. A conductive layer may then be formed on the upper insulation layer 125 and the conductive plug 127, and patterned to form an upper conductive layer/metal wiring 129 that is electrically connected to the conductive plug 127 as shown in a FIG. 4. Therefore, the conductive plug 127 electrically connects the second electrode 123 to the upper conductive layer 129. The conductive plug 127 may be formed by a planarization process after deposition of the conductive material for filling the contact hole 126.

The conductive plug 127 may also be formed by a chemical vapor deposition process and/or a physical vapor deposition process using aluminum (Al), aluminum-copper (Al—Cu) alloy, aluminum-copper-silicon (Al—Cu—Si) alloy, tungsten silicide, copper (Cu), tungsten titanium (TiW), tantalum (Ta), molybdenum (Mo), and/or tungsten (W). The upper conductive layer 129 may be formed of the same material as that of the conductive plug 127. As such, the conductive plug 127 and the upper conductive layer 129 may be formed by a single process. In particular, the conductive material may be formed on both the upper insulation layer 125 and in the contact hole 126 exposing the second electrode 123, and then the conductive material may be patterned to form on upper conductive layer electrically connected to the second electrode 123.

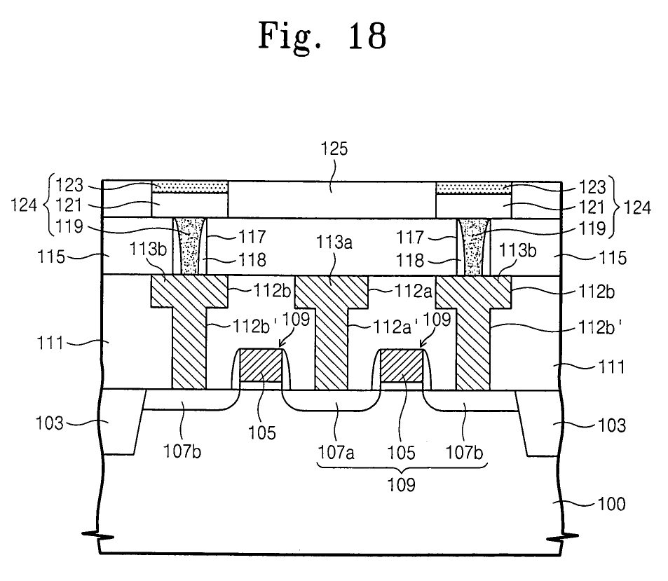

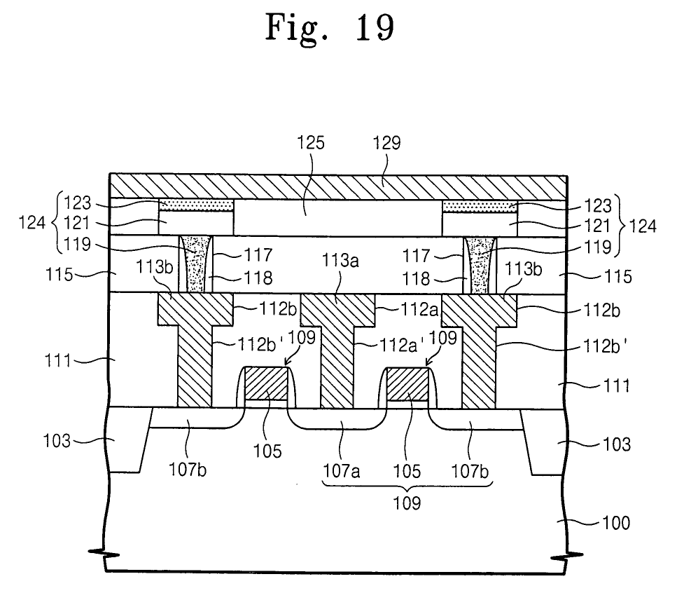

FIGS. 18 and 19 are cross-sectional views illustrating methods of fabricating a phase-changeable memory device including a chalcogen compound layer formed by sputtering methods in accordance with further embodiments of the present invention. In particular, the conductive layer may be in direct contact with the second electrode, and the process for forming the contact hole may be omitted.

Referring now to FIG. 18, after the variable resistor/phase-changeable memory cell 124 is formed as shown in a FIG. 13, the upper insulation layer 125 is formed on the lower insulation layer 115, and a planarization process is performed. As a result, the upper insulation layer 125 is about the same height as the second electrode 123. The planarization process may be implemented using chemical mechanical polishing, etch-back, etc.

Referring to FIG. 19, a conductive material is formed on the upper insulation layer 125 and the second electrode 123, and the conductive material is patterned to form an upper conductive layer 129. The upper conductive layer 129 may be formed by a chemical vapor deposition process and/or a physical vapor deposition process, for example, using aluminum (Al), aluminum-copper (Al—Cu) alloy, aluminum-copper-silicon (Al—Cu—Si) alloy, tungsten silicide, copper (Cu), tungsten-titanium (TiW), tantalum (Ta), molybdenum (Mo), or tungsten (W). Thus, the upper conductive layer 129 is in direct contact with the second electrode 123.

Thus, according to some embodiments of the present invention, a chalcogen compound layer is formed by sputtering using a DC pulse that switches between a positive DC bias voltage and a negative DC bias voltage, thereby reducing the likelihood of ion accumulation on the target. As such, the chalcogen compound layer may be formed having excellent properties and a smaller crystal structure.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

1. A method of sputtering to deposit a target material onto a substrate, the method comprising:
supplying an ionized gas to the substrate and the target material;
applying a first DC bias voltage having a polarity opposite that of the ionized gas to the target material to attract ions theretoward; and
intermittently applying a second DC bias voltage having a polarity opposite that of the first DC bias voltage to the target material to reduce ion accumulation thereon.

2. The method of claim 1, further comprising:
depositing the target material onto the substrate responsive to applying the first DC bias voltage and intermittently applying the second DC bias voltage to the target material.

3. The method of claim 1, wherein intermittently applying a second DC bias voltage comprises intermittently applying the second DC bias for a duration that is shorter than a duration of applying the first DC bias voltage over a predetermined time period.

4. The method of claim 1, wherein intermittently applying a second DC bias voltage comprises periodically applying the second DC bias voltage to the target material.

5. The method of claim 4, wherein applying a first DC bias voltage to the target material and periodically applying the second DC bias voltage to the target material comprises applying a DC pulse that periodically switches between the first DC bias voltage and the second DC bias voltage.

6. The method of claim 5, wherein applying a DC pulse comprises applying a squarewave to the target material, wherein a period of the squarewave includes a first portion having an amplitude at the first DC bias voltage for a first duration and a second portion having an amplitude at the second DC bias voltage for a second duration, and wherein the second duration is less than the first duration.

7. The method of claim 6, wherein the period of the squarewave comprises about 1 μs to about 1 ms, and wherein the second duration comprises about 1 μs to about 100 μs.

8. The method of claim 6, wherein the amplitude of the second portion of the period of the squarewave comprises about 5% to about 95% of the sum of the amplitudes of the first and second portions.

9. The method of claim 1, wherein the first DC bias voltage comprises a negative voltage, and wherein the second DC bias voltage comprises a positive voltage.

10. The method of claim 1, wherein supplying an ionized gas comprises:
supplying an inert gas and a reaction gas to the substrate and the target material; and
ionizing the inert gas and the reaction gas.

11. The method of claim 10, wherein the inert gas comprises argon (Ar), and wherein the reaction gas comprises nitrogen (N).

12. The method of claim 11, wherein the target material comprises chalcogen, and further comprising:
forming a nitrogen-doped chalcogen layer having a resistivity greater than that of chalcogen on the substrate responsive to applying the first DC bias voltage and intermittently applying the second DC bias voltage to the target material.

13. The method of claim 1, wherein the substrate includes a first electrode thereon and wherein the target material comprises a phase-changeable material, and further comprising:
depositing atoms of the target material onto the first electrode to form a phase-changeable layer thereon responsive to applying the first DC bias voltage and intermittently applying the second DC bias voltage; and
forming a second electrode on the phase-changeable layer to define a phase changeable memory cell.

14. A method of fabricating a phase-changeable memory device, the method comprising:
forming a first electrode on a substrate adjacent a target comprising a phase-changeable material;
supplying an ionized gas to the substrate and the target;
applying a first DC bias voltage having a polarity opposite that of the ionized gas to the target to attract ions theretoward;
intermittently applying a second DC bias voltage having a polarity opposite that of the first DC bias voltage to the target to reduce ion accumulation thereon;
depositing a phase-changeable material layer on the first electrode responsive to applying the first DC bias voltage and intermittently applying the second DC bias voltage; and
forming a second electrode on the phase-changeable material layer to define a phase changeable memory cell.

15. The method of claim 14, wherein applying a first DC bias voltage and intermittently applying the second DC bias voltage comprises applying a DC pulse to the target that periodically switches between the first DC bias voltage and the second DC bias voltage.

16. The method of claim 15, wherein applying a DC pulse comprises applying a squarewave to the target, wherein a period of the squarewave includes a first portion having an amplitude at the first voltage for a first duration and a second portion having an amplitude at the second voltage for a second duration, and wherein the second duration is less than the first duration.

17. The method of claim 14, wherein the target comprises chalcogen, and wherein supplying an ionized gas comprises:
supplying an argon (Ar) gas and a nitrogen (N) gas to the substrate and the target material; and
ionizing the argon (Ar) gas and the nitrogen (N) gas,
wherein depositing a phase-changeable material layer on the first electrode comprises forming a nitrogen-doped chalcogen layer having a resistivity greater than that of chalcogen on the substrate responsive to applying the first DC bias voltage and intermittently applying the second DC bias voltage to the target.

18. A sputtering apparatus, comprising:
a substrate;
a target material opposite the substrate;
a gas supply configured to provide an ionized gas to the substrate and the target material; and
a voltage source configured to apply a first DC bias voltage having a polarity opposite that of the ionized gas to the target material to attract ions theretoward and configured to intermittently apply a second DC bias voltage having a polarity opposite that of the first DC bias voltage to the target material to reduce ion accumulation thereon.

19. The apparatus of claim 18, wherein the apparatus is configured to deposit the target material onto the substrate responsive to applying the first DC bias voltage and intermittently applying the second DC bias voltage to the target material.

20. The apparatus of claim 18, wherein the voltage source is configured to apply the first DC bias voltage for a first duration and intermittently apply the second DC bias voltage for a second duration, wherein the first duration is greater than the second duration over a predetermined time period.

21. The apparatus of claim 18, wherein the voltage source is configured to periodically apply the second DC bias voltage to the target material.

22. The apparatus of claim 21, wherein the voltage source comprises a DC pulse generator configured to apply a DC pulse to the target material that periodically switches between the first DC bias voltage and the second DC bias voltage.

23. The apparatus of claim 22, wherein the DC pulse generator comprises:
a DC bias source configured to provide a DC voltage; and
a DC pulse converter configured to convert the DC voltage into a squarewave,
wherein a period of the squarewave includes a first portion having an amplitude at the first DC bias voltage for a first duration and a second portion having an amplitude at the second DC bias voltage for a second duration, and wherein the second duration is less than the first duration.

24. The apparatus of claim 23, wherein the period of the squarewave comprises about 1 μs to about 1 ms, and wherein the second duration comprises about 1 μs to about 100 μs.

25. The apparatus of claim 23, wherein the amplitude of the second portion of the period of the squarewave comprises about 5% to about 95% of the sum of the amplitudes of the first and second portions.

26. The apparatus of claim 18, wherein the first DC bias voltage comprises a negative voltage, and wherein the second DC bias voltage comprises a positive voltage.

27. The apparatus of claim 18, wherein the gas supply is configured to supply an inert gas and a reaction gas to the substrate and the target material.

28. The apparatus of claim 27, wherein the inert gas comprises argon (Ar), wherein the reaction gas comprises nitrogen (N), and wherein the target material comprises chalcogen.

29. The apparatus of claim 28, wherein the apparatus is configured to deposit chalcogen atoms from the target material onto the substrate to form a nitrogen-doped chalcogen layer thereon, wherein the nitrogen-doped chalcogen layer has a resistivity greater than that of chalcogen.

30. The apparatus of claim 29, wherein the nitrogen-doped chalcogen layer comprises about 0.25% to about 25% nitrogen atoms.

31-50. (canceled)
